(19) United States
(12) Patent Application Publication
(10) Pub. No.: US 2024/0110722 A1
(43) Pub. Date: Apr. 4, 2024

(54) LOUVER AND CHARGING DEVICE

(71) Applicant: Komatsu Ltd., Tokyo (JP)

(72) Inventors: Takahiro Kakizaki, Tokyo (JP); Takashi Hirota, Tokyo (JP); Atsushi Miyamoto, Tokyo (JP)

(73) Assignee: Komatsu Ltd., Tokyo (JP)

(21) Appl. No.: 18/273,793

(22) PCT Filed: Feb. 22, 2022
(86) PCT No.: PCT/JP2022/007389

§ 371 Date: Jul. 24, 2023

(30) Foreign Application Priority Data
Feb. 26, 2021 (JP) 2021-030745

(51) Int. Cl. F24F 13/16; F24F 1/029

(52) U.S. Cl. CPC F24F 13/16; F24F 1/029; F24F 7/06

(57) ABSTRACT

The louver 1 includes a first member 2 including a lid portion 22, slits 24 disposed at intervals from the lid portion 22, and rising portions 25 and rising portions 26 extending from peripheral edge portions of the slits 24 toward one side in a depth direction and a second member 3 including a lid portion 32, slits 34 disposed at intervals from the lid portion 32, and rising portions 35 and rising portions 36 extending from the peripheral edge portions of the slits 34 toward the other side in the depth direction. The first member 2 and the second member 3 are disposed to face each other and the slits 24 of the first member 2 and the slits 34 of the second member 3 are disposed to be shifted from each other.

### FIELD

The present disclosure relates to a louver and a charging device.

### BACKGROUND

Patent Literature 1 discloses an example of a louver that can prevent rainwater or the like from intruding into a cabinet when the cabinet is installed outdoors and can improve ventilation performance without impairing waterproof performance. In the technique described in Patent Literature 1, the louver is configured by two types of an inner louver and an outer louver.

### CITATION LIST

### Patent Literature

Patent Literature 1: JP 2007-173330 A

### SUMMARY

### Technical Problem

For example, a charging device for charging a battery loaded on a work vehicle is installed outdoors, in a factory, or the like. Therefore, liquid such as water, dust, or the like is likely to enter the inside of the charging device.

An object of an aspect of the present invention is to improve waterproof performance.

### Solution to Problem

According to an aspect of the present invention, a louver comprises: a first member including a lid portion provided with slits disposed at intervals and rising portions extending from peripheral edge portions of the slits toward one side in a depth direction; and a second member including a lid portion provided with slits disposed at intervals and rising portions extending from peripheral edge portions of the slits toward another side in the depth direction, wherein the first member and the second member are disposed to face each other in a direction in which the rising portions extend, and the slits of the first member and the slits of the second member are disposed to be shifted from each other.

According to another aspect of the present invention, a charging device comprises the louver.

### Advantageous Effects of Invention

According to the present disclosure, waterproof performance can be improved.

### BRIEF DESCRIPTION OF DRAWINGS

FIG. 1 is a perspective view of a charging device including a louver according to an embodiment.

FIG. 2 is a sectional view schematically illustrating the inside of the charging device including the louver according to the embodiment.

FIG. 3 is a perspective view of the louver according to the embodiment viewed from an upward direction in the right front.

FIG. 4 is a perspective view of the louver according to the embodiment viewed from an upward direction in the right rear.

FIG. 5 is a front view of the louver according to the embodiment.

FIG. 6 is a rear view of the louver according to the embodiment.

FIG. 7 is a sectional view of the louver according to the embodiment and is an A-A line sectional arrow view of FIG. 5.

FIG. 8 is a partially enlarged sectional view of the louver according to the embodiment and is a sectional view of the louver viewed from the upward direction in the right front.

FIG. 9 is a perspective view illustrating a first member.

FIG. 10 is a perspective view illustrating a second member.

FIG. 11 is a partially enlarged view of the louver.

FIG. 12 is a schematic diagram for explaining noise leaking from the charging device to the outside.

FIG. 13 is a schematic diagram for explaining interference of noise leaking from the charging device to the outside.

### DESCRIPTION OF EMBODIMENTS

An embodiment according to the present invention is explained below with reference to the drawings. However, the present invention is not limited to this. Components of the embodiment explained below can be combined as appropriate. A part of the components is sometimes not used.

[Charging Device]

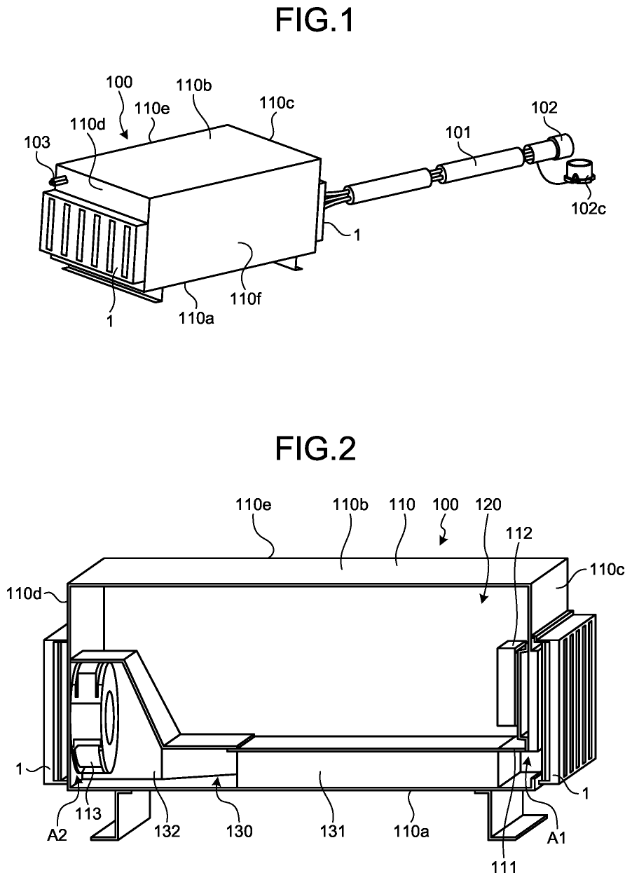

FIG. 1 is a perspective view of a charging device 100 including a louver 1 according to the present embodiment. FIG. 2 is a sectional view schematically illustrating the inside of the charging device 100 including the louver 1 according to the present embodiment. In FIG. 2, various members, devices, and the like disposed on the inside of the charging device 100 are not illustrated. The charging device 100 illustrated in FIG. 1 and FIG. 2 is charging equipment for charging a battery of a not-illustrated work vehicle. The charging device 100 is disposed, for example, in a charging place outdoors, in a factory, or the like. The charging device 100 includes a cable 101 that supplies power to the battery and a plug 102 disposed at the distal end portion of the cable 101. The plug 102 can be inserted into a connector of the work vehicle. A cap 102C covering a terminal portion is detachably disposed on the plug 102. The charging device 100 is supplied with power from a power supply connected via a power cable 103. The power supply is, for example, an AC power source (a commercial power source).

The charging device 100 takes air from the outside into the inside of a housing 110 and discharges the air that have cooled inside to the outside. The louver 1 is disposed in an external air inlet/outlet port of the charging device 100. In the present embodiment, the charging device 100 includes a suction-side louver 1 disposed on a suction side of the charging device 100 and an exhaust-side louver 1 disposed on an exhaust side.

The housing 110 has a box shape. The housing 110 includes a wall portion 110a facing downward, a wall portion 110b facing the wall portion 110a, a wall portion 110c connecting the wall portion 110a and the wall portion 110b, a wall portion 110d, a wall portion 110e, and a wall portion 110f. The wall portion 110d faces the wall portion 110c. The wall portion 110e connects the wall portion 110c and the wall portion 110d. The wall portion 110f faces the wall portion 110e. In the present embodiment, the wall portion 110a, the wall portion 110b, the wall portion 110c, the wall portion 110d, the wall portion 110e, and the wall portion 110f are formed of a plate-like material. In the housing 110, a suction port A1 is formed on the air suction side and an exhaust port A2 is formed on the exhaust side.

The suction-side louver 1 is provided in the suction port A1. The exhaust-side louver 1 is provided in the exhaust port A2.

The air suction port A1 is provided in the wall portion 110c. The suction port A1 is an opening for introducing gas into an electric component housing chamber 120 and a heat sink housing chamber 130. The suction port A1 is covered by the suction-side louver 1. A not-illustrated suction filter is disposed in the suction port A1. The suction filter prevents dust or the like from entering the inside of the housing 110 from the suction port A1.

The air exhaust port A2 is provided in the wall portion 110d. The exhaust port A2 is an opening for discharging gas from the electric component housing chamber 120 and the heat sink housing chamber 130. The exhaust port A2 is covered by the exhaust-side louver 1. A not-illustrated exhaust filter is disposed in the exhaust port A2. The exhaust filter prevents dust or the like from entering the inside of the housing 110 from the exhaust port A2.

The suction port A1 and the exhaust port A2 are disposed in positions facing each other. Consequently, the gas introduced into a heat sink 131 from the suction port A1 is efficiently discharged from the exhaust port A2.

A suction fan 112 is provided in the suction port A1. The suction fan 112 introduces gas into the electric component housing chamber 120. The suction fan 112 sucks gas from the electric component housing chamber 120 to thereby introduce the gas into the electric component housing chamber 120 from the suction port A1 and discharges the gas from the exhaust port A2.

An exhaust fan 113 is provided in the exhaust port A2. The exhaust fan 113 introduces gas into the heat sink housing chamber 130. The exhaust fan 113 sucks gas from the heat sink housing chamber 130 to thereby introduce the gas into the heat sink housing chamber 130 from the suction port A1 and discharges the gas from the exhaust port A2.

A bracket 111 is disposed on the inside of the housing 110. A space above the bracket 111 is the electric component housing chamber 120 and a space below the bracket is the heat sink housing chamber 130. A not-illustrated electric component is disposed in the electric component housing chamber 120. The heat sink 131, which is a heat dissipation member, is disposed in the heat sink housing chamber 130. The suction fan 112 is disposed upstream of the electric component housing chamber 120. A suction-side louver 1 is disposed on the outer side of the housing 110 to face the suction fan 112. A part of the electric component is disposed on the heat sink 131. A duct 132 is connected to a downstream side of the heat sink 131. The exhaust fan 113 is disposed on the downstream side of the duct 132. The exhaust-side louver 1 is disposed on the outer side of the housing 110 to face the exhaust fan 113.

[Louver]

As illustrated in FIG. 1 and FIG. 2, the louver 1 is disposed in an external air inlet/outlet port in the charging device 100. More specifically, the suction-side louver 1 is disposed in the suction port A1 of the charging device 100 and the exhaust-side louver 1 is disposed in the exhaust port A2. The suction-side louver 1 and the exhaust-side louver 1 are configured the same.

In the following explanation, in a state in which the louver 1 is assembled to the charging device 100, a side exposed to the outside is the front and a side facing the housing 110 of the charging device 100, which is an attached portion, is the rear. The front-rear direction is the depth direction of the louver 1. In the present embodiment, left and right means left and right with respect to the front. The left-right direction is the lateral direction of the louver 1. The upward direction is a side orthogonal to the front-rear direction and the left-right direction and directed upward. The downward direction is a side orthogonal to the front-rear direction and the left-right direction and directed downward. The up-down direction is the longitudinal direction of the louver 1. A front-rear axis is an X axis, an up-down axis is a Y axis, and a left-right axis is a Z axis.

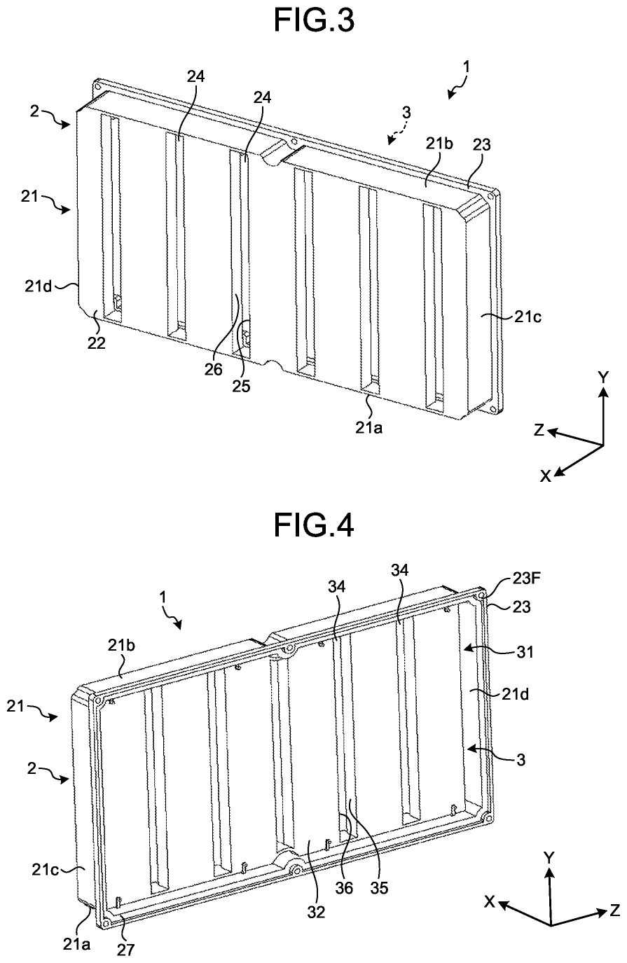

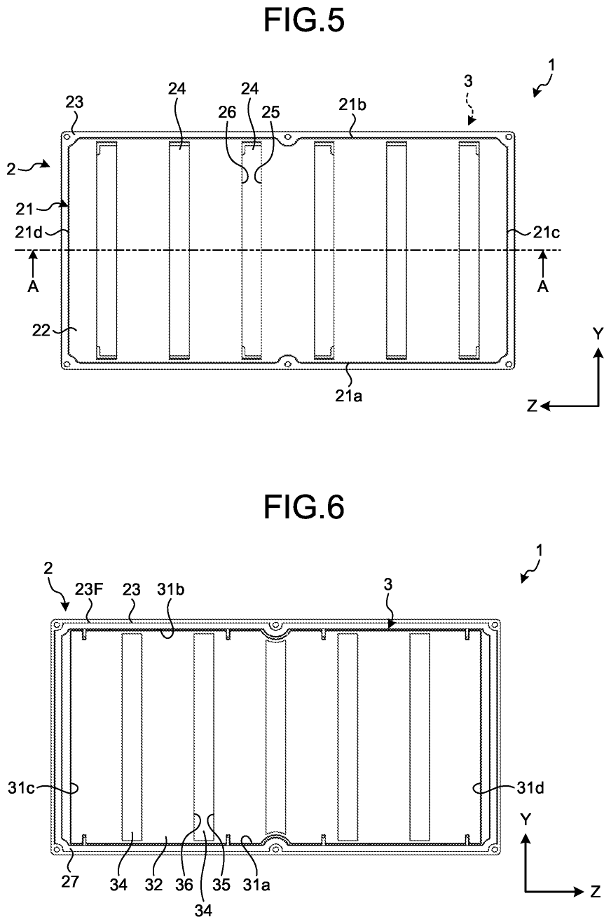

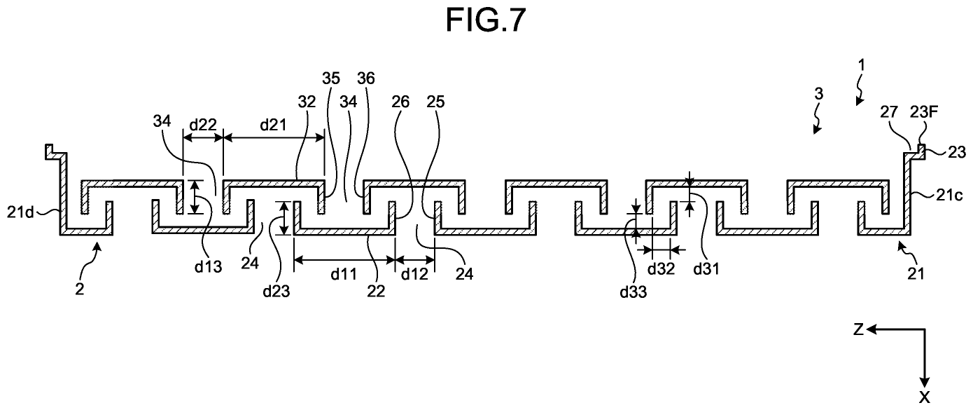

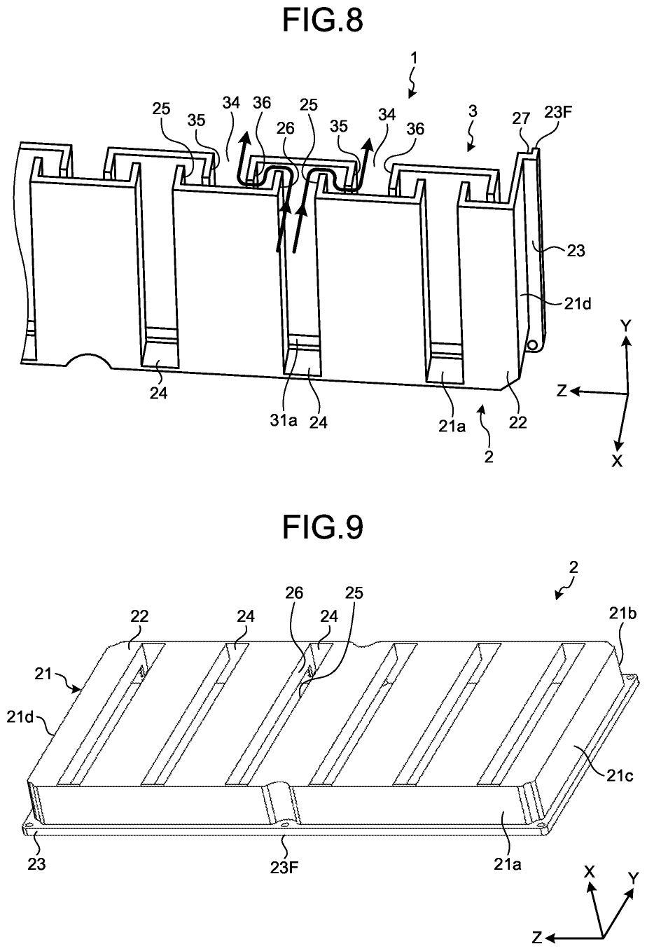

FIG. 3 is a perspective view of the louver according to the present embodiment viewed from the upward direction in the right front. FIG. 4 is a perspective view of the louver according to the present embodiment viewed from the upward direction in the right rear. FIG. 5 is a front view of the louver according to the present embodiment. FIG. 6 is a rear view of the louver according to the present embodiment. FIG. 7 is a sectional view of the louver according to the present embodiment and is an A-A line sectional arrow view of FIG. 5. FIG. 8 is a partially enlarged sectional view of the louver according to the present embodiment and is a sectional view of the louver viewed from the upward direction in the right front. As illustrated in FIG. 3 to FIG. 8, the louver 1 includes a first member 2 and a second member 3. The first member 2 and the second member 3 are integrally assembled to the louver 1.

FIG. 9 is a perspective view illustrating the first member. As illustrated in FIG. 9, the first member 2 includes a main body portion 21, a lid portion 22, and a flange portion 23. The main body portion 21 is formed in a rectangular tube shape by a wall portion 21a, a wall portion 21b, a wall portion 21c, and a wall portion 21d. The wall portion 21b is disposed to face the wall portion 21a. The wall portion 21c connects the wall portion 21a and the wall portion 21b. The wall portion 21d is disposed to face the wall portion 21c. The lid portion 22 is disposed at the front end portion in the depth direction of the main body portion 21. The lid portion 22 is formed of a plate-like member. The flange portion 23 is disposed at the rear end portion in the depth direction of the main body portion 21. The flange portion 23 spreads in a flange shape from the rear end portion of the main body portion 21. The flange portion 23 is disposed to face the lid portion 22. The flange portion 23 is formed in a rectangular frame shape. A rear surface 23F facing rearward of the flange portion 23 faces the housing 110 of the charging device 100.

The first member 2 includes the lid portion 22 provided with slits 24 disposed at intervals and pairs of rising portions 25 and 26 extending from the peripheral edge portions of the slits 24 toward one side in the depth direction.

The slits 24 are formed in the lid portion 22. In the present embodiment, the slits 24 extend in the longitudinal direction. A plurality of slits 24 are disposed side by side in the lateral direction of the lid portion 22. In the present embodiment, six slits 24 are disposed. As illustrated in FIG. 7, the width of the lid portion 22 located between the slits 24 adjacent to each other in the lateral direction is represented as d11. The width d11 is, for example, 40 [mm]. The width of the slits 24 is represented as d12. The width d12 is, for example, 17.5 [mm].

The rising portions 25 and the rising portions 26 are disposed to face each other across the slits 24. The rising portions 25 and the rising portions 26 are similarly configured. The rising portions 25 and the rising portions 26 are formed of a rectangular plate material. The rising portions 25 and the rising portions 26 are erected perpendicularly to the lid portion 22 in the depth direction. As illustrated in FIG. 9, the rising portions 25 and the rising portions 26 connect the wall portion 21a and the wall portion 21b. The width in the depth direction of the rising portions 25 and the rising portions 26 illustrated in FIG. 7 is represented as d13. The width d13 is, for example, 15 [mm].

As illustrated in FIG. 4, FIG. 7, and FIG. 8, a stepped portion 27 is disposed in the flange portion 23 of the first member 2. A not-illustrated sealing member that seals a space between the first member 2 and the housing 110, which is an attached portion, is engaged with the stepped portion 27. The stepped portion 27 is formed on a surface 23F facing the rear of the flange portion 23. The stepped portion 27 is formed in a stepped shape on the surface 23F facing the rear of the flange portion 23. The stepped portion 27 is capable of housing the sealing member. The peripheral edge portion of the louver 1 and the peripheral edge portions of the suction port A1 and the exhaust port A2 of the housing 110 of the charging device 100 are sealed by the sealing member housed in the stepped portion 27.

In a state in which the second member 3 is assembled to the first member 2, the sealing member is pressed against the housing 110 of the charging device 100 to seal the peripheral edge portion of the second member 3. The sealing member has a size and a shape for closing a gap S (see FIG. 11) explained below.

As illustrated in FIGS. 3 to 8, the first member 2 and the second member 3 are disposed to face each other. The second member 3 is integrally assembled to the first member 2. More specifically, the second member 3 is assembled in a state in which the second member 3 is housed on the inside of the main body portion 21 of the first member 2.

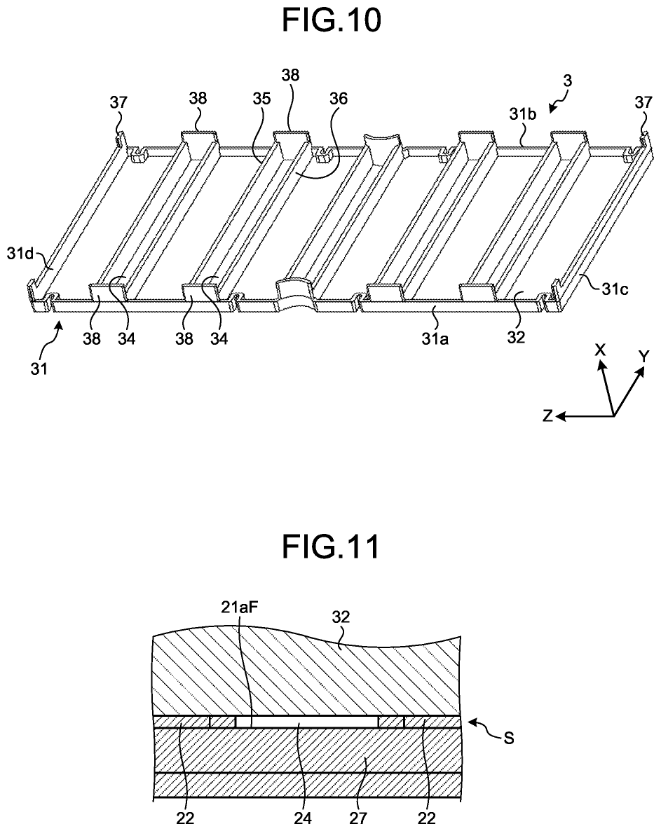

FIG. 10 is a perspective view illustrating the second member. As illustrated in FIG. 10, the second member 3 includes a main body portion 31 and a lid portion 32. The main body portion 31 is formed in a rectangular tube shape having an outer periphery smaller than the inner periphery of the main body portion 21 of the first member 2. The main body portion 31 is formed in a rectangular tube shape by a wall portion 31a, a wall portion 31b, a wall portion 31c, and a wall portion 31d. The wall portion 31b is disposed to face the wall portion 31a. The wall portion 31c connects the wall portion 31a and the wall portion 31b. The wall portion 31d is disposed to face the wall portion 31c. The lid portion 32 is disposed at the rear end portion of the main body portion 31 in the depth direction. The lid portion 32 is formed of a plate-like member.

As illustrated in FIG. 3 to FIG. 8, in a state in which the second member 3 is assembled to the first member 2, the wall portion 31a faces the wall portion 21a, the wall portion 31b faces the wall portion 21b, the wall portion 31c faces the wall portion 21c, and the wall portion 31d faces the wall portion 21d.

As illustrated in FIG. 10, the second member 3 includes the lid portion 32 provided with slits 34 disposed at intervals and pairs of rising portions 35 and 36 extending from the peripheral edge portions of the slits 34 toward the other side in the depth direction.

The slits 34 are formed in the lid portion 32. In the present embodiment, the slits 34 extend in the longitudinal direction. The plurality of slits 34 are disposed side by side in the lateral direction of the lid portion 32. In the present embodiment, five slits 34 are disposed.

As illustrated in FIG. 3 to FIG. 8, the slits 34 are disposed to be shifted from the slits 24 in the lateral direction in the state in which the second member 3 is assembled to the first member 2. In a state in which the second member 3 is assembled to the first member 2, the inside of the housing 110 is invisible when viewed from the outer side of the housing 110. More specifically, in the state in which the second member 3 is assembled to the first member 2, the lid portion 32 of the second member 3 is present behind the slits 24 when viewed from the front. In the state in which the second member 3 is assembled to the first member 2, the lid portion 22 of the first member 2 is present in the front of the slits 34 when viewed from the rear.

As illustrated in FIG. 7, the width of the lid portion 32 located between the slits 34 adjacent to each other in the lateral direction is represented as d21. The width d21 is, for example, 40 [mm]. In the present embodiment, d21=d11. The width of the slits 34 is represented as d22. The width d22 is, for example, 17.5 [mm]. In the present embodiment, d22=d12.

The rising portions 35 and the rising portions 36 are disposed to face each other across the slits 34. The rising portions 35 and the rising portions 36 are similarly configured. The rising portions 35 and the rising portions 36 are formed of a rectangular plate material. The rising portions 35 and the rising portions 36 are erected perpendicularly to the lid portion 32 in the depth direction. As illustrated in FIG. 10, the rising portions 35 and the rising portions 36 connect the wall portion 31a and the wall portion 31b. The width in the depth direction of the rising portions 35 and the rising portions 36 illustrated in FIG. 7 is represented as d23. The width d23 is, for example, 15 [mm]. In the present embodiment, d23=d13.

The first member 2 and the second member 3 are disposed to face each other in a direction in which the rising portions 25 and the rising portions 26 of the first member 2 and the rising portions 35 and the rising portions 36 of the second member 3 extend. In the present embodiment, the rising portions 25 and the rising portions 26 of the first member 2 and the rising portions 35 and the rising portions 36 of the second member 3 partially overlap in the depth direction.

As illustrated in FIG. 10, the second member 3 includes four leg portions 37 and ten leg portions 38. The leg portions 37 and the leg portions 38 project further forward than the rising portions 35 and the rising portions 36. The leg portions 37 are erected from corner portions of the main body portion 31. The leg portions 37 extends forward. The leg portions 38 are erected from the upper end portions and the lower end portions of the slits 34. The leg portions 38 extend forward. The front end portions of the leg portions 37 and the front end portions of the leg portions 38 are in contact with the lid portion 22 of the main body portion 21 of the first member 2. The second member 3 is positioned with respect to the first member 2 in the depth direction by the leg portions 37 and the leg portions 38. The rising portions 35 and the rising portions 36 are disposed to be separated from the lid portion 22 of the first member 2. Consequently, a gas flow path is formed among the lid portion 22, the rising portions 25, and the rising portions 26 of the first member 2 and the lid portion 32, the rising portions 35, and the rising portions 36 of the second member 3.

As illustrated in FIG. 7, in the gas flow path, the width in the depth direction between the rear end portions of the rising portions 26 and the lid portion 32 is represented as d31, the width in the lateral direction between the rising portions 26 and the rising portions 36 is represented as d32, and the width in the depth direction between the front end portions of the rising portions 36 and the lid portion 22 is represented as d33. It is preferable that d31, d32, and d33 are the same. The width d12 of the slits 24, the width d22 of the slits 34, and the widths d31, d32, and d33 of the gas flow path satisfy the relation of d12=2×d31 (d12=d22, d31=d32, d31=d33).

FIG. 11 is a partially enlarged diagram of the louver. As illustrated in FIG. 11, the lower end portion of the second member 3 forms a gap S between the lower end portion and the first member 2. More specifically, an upward-facing surface 21aF of the wall portion 21a and the lower end portion of the lid portion 32 are not in close contact and the gap S is formed.

The members of the louver 1 configured as explained above are formed by resin molding.

[Action]

A flow of air is explained. The suction fan 112 and the exhaust fan 113 operate, air is taken into the inside from the outside of the housing 110 from the suction-side louver 1, and the air that has cooled the inside is exhausted to the outside from the exhaust-side louver 1. More specifically, the air is taken into the inside of the suction-side louver 1 from the slits 24 of the suction-side louver 1 of the charging device 100. The air flowing in from the slits 24 passes through a flow path formed between the first member 2 and the second member 3 and flows into the inside from the slits 34 passing through the suction port A1 of the housing 110. The flowing-in air flows into the electric component housing chamber 120 and the heat sink housing chamber 130. When the air passes through the electric component housing chamber 120 and the heat sink housing chamber 130, the disposed components are cooled. Then, the air that has cooled the inside of the housing 110 passes through the exhaust port A2 and is taken into the inside of the exhaust-side louver 1 from the slits 34 of the exhaust-side louver 1. The air flowing in from the slits 34 passes through the flow path formed between the first member 2 and the second member 3 and is discharged to the outside from the slits 24.

Next, waterproof performance is explained. In the louver 1, the lid portion 32 of the second member 3 is present behind the slits 24 and the lid portion 22 of the first member 2 is present in front of the slits 34. Therefore, for example, liquid such as water is restricted from directly flowing into the inside of the housing 110 from the louver 1.

A case in which liquid such as water adheres to the louver 1 is explained. In the following explanation, water is explained as an example of the liquid. The water obliquely blowing into the louver 1 is restricted from intruding into the inside by the rising portions 35 and the rising portions 36 of the second member 3. The water adhering to the lid portion 22 of the first member 2 directly flows downward along the lid portion 22 and does not intrude into the inside of the louver 1. The water adhering to the rising portions 25 and the rising portions 26 of the first member 2 or the lid portion 32 of the second member 3 flows downward along the members. Then, the water reaches the wall portion 21a and the wall portion 31a in the lower portions of the slits 24. The peripheral edge portion of the louver 1 and the peripheral edge portion of the housing 110 of the charging device 100 are sealed by the sealing member housed in the stepped portion 27. In the wall portion 21a and the wall portion 31a, inclination from the rear to the front, in other words, from the inner side to the outer side is formed as a draft at the time of molding. Consequently, the water flows along the wall portion 21a and the wall portion 31a and is discharged to the outside.

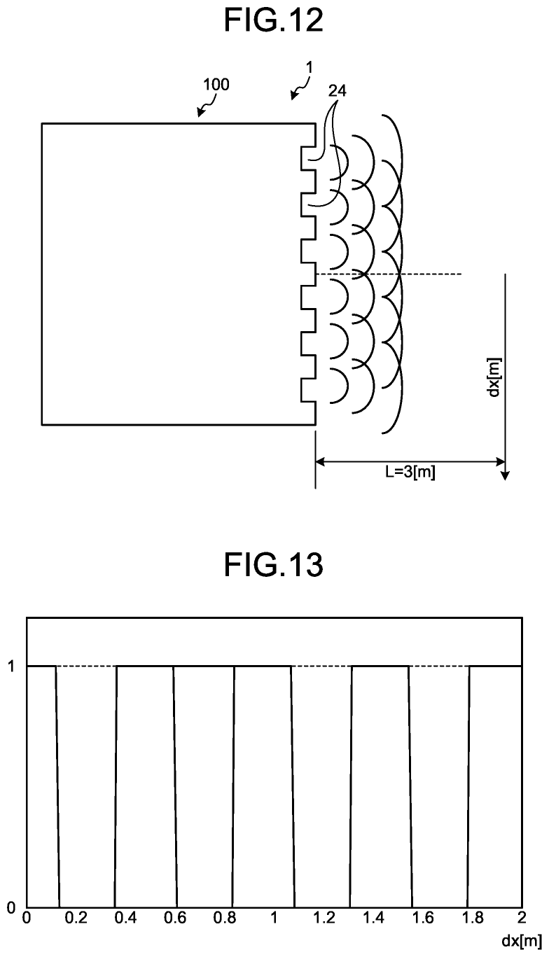

Next, noise of the charging device 100 including the louver 1 is explained with reference to FIG. 12 and FIG. 13. FIG. 12 is a schematic diagram illustrating noise leaking from the charging device to the outside. FIG. 13 is a schematic diagram illustrating interference of the noise leaking from the charging device to the outside. For simplification of explanation, a case in which one louver 1 is disposed in the charging device 100 is explained. During operation of the charging device 100, high-frequency switching noise of a transformer occurs. FIG. 12 schematically illustrates the slits 24 of the louver 1 and spread of sounds leaking from the slits 24 at the time when the charging device 100 is viewed from above. As illustrated in FIG. 12, sound on the inside of the charging device 100 spread to the outer side from the slits 24.

The sounds spreading from the slits 24, in other words, the noise during the operation of the charging device 100 changes with the distance between the user and the slits 24, the wavelength, that is, the frequency of the sounds, a slit pitch (an interval between the centers of the slits), which is the interval between the adjacent slits 24, and the like as interference conditions. The sounds spreading from the slits 24 interfere with one another and intensify one another or weaken one another. Depending on the position of the user, the sounds spreading from the slits 24 can be heard more loudly in a certain place due to mutual intensification of the sounds and can be heard less loudly in a certain place due to mutual weakening of the sounds.

For example, the slit width d11 is set to 17.5 [mm], the slit pitch is set to 64 [mm], the sound frequency is set to 100 [Hz], and the distance L from the slits 24 is set to 3 [m]. In this case, assuming that the wavelength of the sounds is represented as λ, the distance in the lateral direction of the charging device 100 is represented as dx, the distance in the direction away from the slits 24 is represented as L, and m is set to a natural number, the sounds are intensified one another in a position where the following Formula 1 holds and the sounds are weakened one another in a position where Formula 2 holds.

dx/L=λ/2×2m (1)

dx/L=λ/2×(2m+1) (2)

FIG. 13 illustrates a relation between the position of the user and the magnitude of the noise at the distance L=3 [m] from the slits 24. In FIG. 13, a distance dx in the horizontal direction of the charging device 100 is set as the horizontal axis and the wavelength of sound is set as the vertical axis. As illustrated in FIG. 13, it has been successfully confirmed that, under the conditions explained above, loudness appears in the sound at a period of dx of approximately 30 [cm]. When the user feels that the sound is noisy, it is possible to improve hearing of the sound by adjusting the angle of the charging device 100.

[Effects]

As explained above, in the present embodiment, the slits 24 of the first member 2 and the slits 34 of the second member 3 are disposed to be shifted from each other in the lateral direction. In the present embodiment, the lid portion 32 of the second member 3 is present behind the slits 24 and the lid portion 22 of the first member 2 is present in front of the slits 34. According to the present embodiment, it is possible to restrict the inside of the housing 110 from being seen. According to the present embodiment, it is possible to restrict water from intruding into the inside of the housing 110 from the louver 1.

In the present embodiment, the slits 24 of the first member 2 and the slits 34 of the second member 3 extend in the longitudinal direction. In the present embodiment, since the water adhering to the lid portion 22 of the first member 2 directly flows downward along the lid portion 22, it is possible to restrict the water from intruding into the inside of the louver 1. In the present embodiment, it is possible to restrict the water adhering to the lid portion 22 of the first member 2 from intruding into the inside of the louver 1.

In the present embodiment, the rising portions 25 and the rising portions 26 of the first member 2 and the rising portions 35 and the rising portions 36 of the second member 3 partially overlap in the depth direction. In the present embodiment, the water obliquely blowing into the slits 24 can be restricted from intruding into the inside by the rising portions 35 and the rising portions 36 of the second member 3. In the present embodiment, it is possible to secure a flow path of air sucked into the inside of the housing 110 and a flow path of air discharged to the outside of the housing 110. Further, in the present embodiment, it is possible to reduce the thickness of the louver 1 in the depth direction.

In the present embodiment, the first member 2 includes the stepped portion 27 with which the sealing member for sealing the space between the first member 2 and the housing 110 of the charging device 100 is engaged. According to the present embodiment, the peripheral edge portion of the louver 1 and the peripheral edge portion of the housing 110 of the charging device 100 can be sealed by the sealing member.

In the present embodiment, the gap S is formed between the lower end portion of the second member 3 and the first member 2. According to the present embodiment, the water adhering to the rising portions 25 and the rising portions 26 of the first member 2 or the lid portion 32 of the second member 3 can be discharged to the outside along the wall portion 21a and the wall portion 31a by the draft of the wall portion 21a and the wall portion 31a and the sealing member.

As explained above, according to the present embodiment, it is possible to reliably restrict the water from entering the housing 110 from the louver 1. The present embodiment can improve waterproof performance.

In the present embodiment, during the operation of the charging device 100, noises leaking from the slits 24 of the louver 1 are intensified one another and heard more loudly in a certain place and are weakened one another and heard more less loudly in a certain place depending on the position of the user. In the present embodiment, for example, hearing of sound can be improved by adjusting the angle of the charging device 100.

Although the present embodiment is explained above, the present embodiment is not limited by the content explained above. The constituent elements explained above include constituent elements that can be easily assumed by those skilled in the art and constituent elements that are substantially the same, that is, constituent elements in a so-called equivalent range. Further, the constituent elements explained above can be combined as appropriate. Further, various omissions, substitutions, or changes of the constituent elements can be made without departing from the gist of the present embodiment.

The rising portions 25 and the rising portions 26 of the first member 2 and the rising portions 35 and the rising portions 36 of the second member 3 overlap in the depth direction in the present embodiment but may not overlap. The rear end portions of the rising portions 25 and the rising portions 26 and the front end portions of the rising portions 35 and the rising portions 36 may be present in the same positions in the depth direction.

It is explained in the above explanation that the rising portions 25 and the rising portions 26 of the first member 2 and the rising portions 35 and the rising portions 36 of the second member 3 rise perpendicularly to the lid portion 22 or the lid portion 32 but are not limited to this. The rising portions 25 and the rising portions 26 and the rising portions 35 and the rising portions 36 may be inclined with respect to the lid portion 22 or the lid portion 32 rather than being perpendicular thereto. The rising portions 25 and the rising portions 26 and the rising portions 35 and the rising portions 36 may be connected to the lid portion 22 or the lid portion 32 via a curved portion.

### REFERENCE SINGS LIST

1 LOUVER
2 FIRST MEMBER
21 MAIN BODY PORTION
21a WALL PORTION
21aF SURFACE
21b WALL PORTION
21c WALL PORTION
21d WALL PORTION
22 LID PORTION
23 FLANGE PORTION
24 SLIT
25 RISING PORTION
26 RISING PORTION
27 STEPPED PORTION
3 SECOND MEMBER
31 MAIN BODY PORTION
31a WALL PORTION
31b WALL PORTION
31c WALL PORTION
31d WALL PORTION
32 LID PORTION
34 SLIT
35 RISING PORTION
36 RISING PORTION
37 LEG PORTION
38 LEG PORTION
100 CHARGING DEVICE
101 CABLE
102 PLUG
103 POWER SUPPLY CABLE
110 HOUSING
110a WALL PORTION
110b WALL PORTION
110c WALL PORTION
110d WALL PORTION
110e WALL PORTION
110f WALL PORTION
112 SUCTION FAN
113 EXHAUST FAN
120 ELECTRIC COMPONENT HOUSING CHAMBER
130 HEAT SINK HOUSING CHAMBER
131 HEAT SINK
132 DUCT
SUCTION PORT A1
A2 EXHAUST PORT
S GAP

1. A louver comprising:
a first member including a lid portion provided with slits disposed at intervals and rising portions extending from peripheral edge portions of the slits toward one side in a depth direction; and
a second member including a lid portion provided with slits disposed at intervals and rising portions extending from peripheral edge portions of the slits toward another side in the depth direction, wherein
the first member and the second member are disposed to face each other in a direction in which the rising portions extend, and
the slits of the first member and the slits of the second member are disposed to be shifted from each other.

2. The louver according to claim 1, wherein
the rising portions of the first member are disposed as a pair to face each other across the slits of the first member, and
the rising portions of the second member are disposed as a pair to face each other across the slits of the second member.

3. The louver according to claim 1, wherein
the slits of the first member and the slits of the second member extend in a longitudinal direction.

4. The louver according to claim 3, wherein
the rising portions of the first member and the rising portions of the second member partially overlap in the depth direction.

5. The louver according to claim 1, further comprising
a stepped portion that is disposed on an outer peripheral portion of the first member and with which a sealing member for sealing a space between the first member and an attached portion is engaged.

6. The louver according to claim 5, wherein
a lower end portion of the second member forms a gap between the lower end portion and the first member.

7. A charging device comprising the louver according to claim 1.

8. The charging device according to claim 7, further comprising a transformer in which high-frequency switching noise occurs.
